(19) United States
(12) Patent Application Publication
(10) Pub. No.: US 2025/0383372 A1
(43) Pub. Date: Dec. 18, 2025

(54) Inspection Apparatus

(71) Applicant: KABUSHIKI KAISHA NIHON MICRONICS, Tokyo (JP)

(72) Inventors: Katsuo YASUTA, Tokyo (JP); Hideki IKEUCHI, Tokyo (JP); Jun SHIRATO, Tokyo (JP); Takatoshi HARATA, Tokyo (JP)

(73) Assignee: KABUSHIKI KAISHA NIHON MICRONICS, Tokyo (JP)

(21) Appl. No.: 19/206,457

(22) Filed: May 13, 2025

(30) Foreign Application Priority Data
Jun. 17, 2024 (JP) 2024-097421

(51) Int. Cl. G01R 1/07; G01R 1/04; G01R 1/073; G01R 1/44

(52) U.S. Cl. CPC G01R 1/071; G01R 1/04; G01R 1/0416; G01R 1/073; G01R 1/44

(57) ABSTRACT

An inspection apparatus includes: a wafer fixing mechanism unit configured to support a wafer including a device under test having an electrode terminal on one surface and an optical input/output unit on the other surface; an optical probe provided on the one surface side of the wafer, and configured to transmit/receive an optical signal to/from the optical input/output units of the device under test; a conductive probe provided on the other surface side of the wafer, and electrically contacted with the electrode terminal of the device under test; and a wafer non-contact state maintaining unit which is a planar member having an opening in a center portion, and configured to maintain a distance from the wafer by intaking/exhausting pressurized air with respect to the wafer and to enable access to the device under test on the wafer through the opening.

### CROSS-REFERENCE TO RELATED APPLICATIONS

The present application claims priority under 35 U.S.C. § 119 to Japanese Patent Application No. 2024-097421 filed on Jun. 17, 2024. The contents of this application are incorporated herein by reference in their entirety.

### TECHNICAL FIELD

The present disclosure relates to an inspection apparatus, and is applicable to, for example, an inspection apparatus used for testing of semiconductor devices formed on wafers.

### BACKGROUND ART

For example, during a manufacturing process of semiconductor devices, an inspection apparatus (tester) provides test signals to each semiconductor device on a wafer through a probe card and a probe to be connected to the inspection apparatus, and the inspection apparatus acquires a response signal from each semiconductor device to test the semiconductor devices. When testing such semiconductor devices, a prober is used to bring probes into contact with predetermined positions of the semiconductor devices on the wafer.

Conventionally, there are two main methods for a prober to contact conductive probes on both sides of a wafer.

A first method is to move a position of a ring which fixes an outer periphery of a wafer in X, Y and θ directions, and then to apply conductive probes or the like to the wafer from above and below simultaneously. For example, a technique described in Patent Literature 1 is an example of the first method. The technique described in Patent Literature 1 includes placing a wafer on a conductive stage, providing an upper probe electrode which is in contact with the wafer from an upper surface side and a lower probe electrode which is in contact with a stage electrode from a lower surface side so that a measurement circuit connected to the upper probe electrode and the lower probe electrode measures electrical characteristics.

The second method is to move a position of a ring which fixes an outer periphery of a wafer in X, Y and θ directions, then to place a small flat plate on a lower surface of the wafer and contact conductive probes from above. For example, a technique described in Patent Literature 2 is an example of the second method. Patent Literature 2 discloses a configuration in which a chuck plate holds an edge of a wafer, and a probing stage supports a lower surface of the wafer (refer to FIG. 6 in Patent Literature 2).

### CITATION LIST

### Patent Literature

Patent Literature 1: Japanese Patent Application Laid-Open Publication No. 2004-273985
Patent Literature 2: Japanese Patent Application Laid-Open Publication No. 2004-140296

### SUMMARY OF INVENTION

### Technical Problem

However, there is a problem that, when the probe is brought into contact with the wafer placed on the stage from below, the wafer is lifted upward from the stage, causing the wafer to warp.

Moreover, there is also a problem that, when a warpage of a wafer is large, a needle pressure of the probe applied to an electrode terminal of the semiconductor device on the wafer becomes uneven, and an amount of contact pressing becomes uneven.

Accordingly, in view of the above-described problems, the present disclosure aims to provide an inspection apparatus capable of steadily levitating a wafer provided with a device under test from a chuck, and bringing the wafer into contact with terminals of the device under test from one or both sides of the wafer while the chuck (wafer holding unit) and the wafer are in a non-contact state.

### Solution to Problem

In order to solve such problems, an inspection apparatus according to the present disclosure includes: a wafer fixing mechanism unit configured to support a wafer, the wafer including a device under test, the device under test having an electrode terminal on one surface and an optical input/output unit on the other surface; an optical probe provided on the one surface side of the wafer, the optical probe configured to transmit/receive an optical signal to/from the optical input/output units of the device under test; a conductive probe provided on the other surface side of the wafer, the conductive probe electrically contacted with the electrode terminal of the device under test; and a wafer non-contact state maintaining unit which is a planar member having an opening in a center portion, the wafer non-contact state maintaining unit configured to maintain a distance from the wafer by intaking/exhausting pressurized air with respect to the wafer and to enable access to the semiconductor device on the wafer through the opening.

### Advantageous Effects of Invention

According to the present disclosure, it is possible to steadily levitate a wafer provided with a device under test from a chuck, and to bring the wafer into contact with terminals of the device under test from one or both sides of the wafer while the chuck (wafer holding unit) and the wafer are in a non-contact state.

### BRIEF DESCRIPTION OF DRAWINGS

FIG. 1 is an explanatory diagram for explaining a structure of an air bearing unit and a wafer according to an embodiment.

FIG. 2 is an overall configuration diagram illustrating an overall configuration of a prober according to the embodiment.

FIG. 3 is a top view diagram illustrating a configuration of a wafer drive mechanism unit according to the embodiment in a plan view.

FIG. 4 is an explanatory diagram for explaining a structure of an air bearing unit and a wafer according to a modified embodiment (aspect 1).

FIG. 5 is an explanatory diagram for explaining a structure of the air bearing unit and the wafer according to a modified embodiment (aspect 2).

### DESCRIPTION OF EMBODIMENTS

### (A) Principal Embodiment

Hereinafter, embodiments of an inspection apparatus according to the present disclosure will be described in detail with reference to the drawings.

In the description of the following drawings to be explained, the identical reference sign is attached to the equivalent part. However, it should be noted that the drawings are schematic and, for example, the ratio of the thickness of each component element differs from an actual thing. Moreover, the part from which the relation and ratio of a mutual size differ also in mutually drawings is included. Moreover, the embodiment described hereinafter merely exemplifies the device and method for materializing the technical ideas of the present disclosure; and the embodiment does not specify the material, shape, structure, placement, etc. the components are not limited to those described in the embodiments.

### (A-1) Configuration of Embodiment

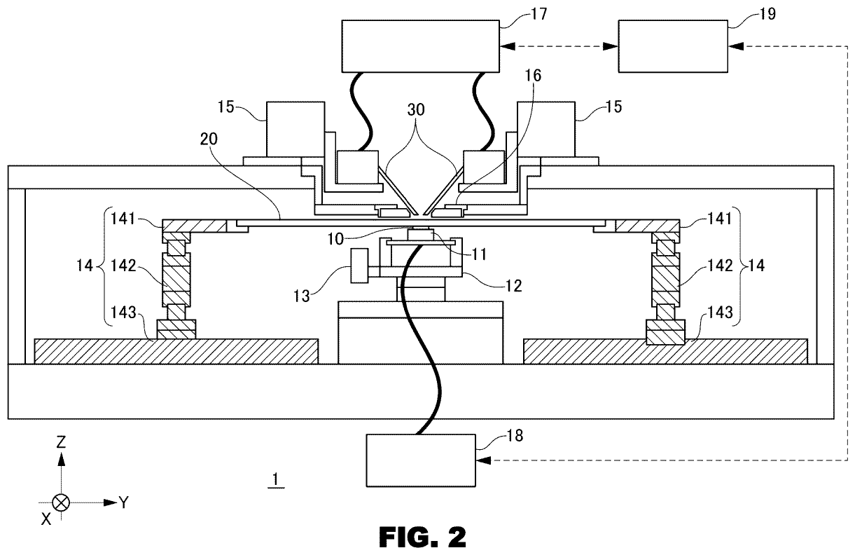

FIG. 2 is an overall configuration diagram illustrating an overall configuration of a prober according to the embodiment.

In FIG. 2, a prober (inspection apparatus) 1 according to the embodiment includes: a conductive probe assembly 11 including a plurality of conductive probes 10; a conductive probe stage 12; an alignment camera 13; a wafer drive mechanism unit 14; a wafer 20; an optical probe 30; an optical probe manipulator 15; an air bearing unit 16; an optical transmitter/receiver unit 17; an electrical signal transmitter/receiver unit 18; and a control unit 19.

The optical transmitter/receiver unit 17, the electrical signal transmitter/receiver unit 18, and the control unit 19 are mounted as a part of the inspection apparatus for testing characteristics of a semiconductor device 200.

The optical transmitter/receiver unit 17 is configured to transmit an optical signal to the semiconductor device 200 and to receive an optical signal from the semiconductor device 200 through the optical probe 30 under control of the control unit 19 in the inspection apparatus.

The electrical signal transmitter/receiver unit 18 is configured to transmit an electrical signal to the semiconductor device 200 and to receive an electrical signal from the semiconductor device 200 through the conductive probe 10 under control of the control unit 19 in the inspection apparatus.

### [Wafer 20 and Semiconductor Device 200]

A plurality of semiconductor devices 200 are formed on the wafer 20.

As an example disclosed in the embodiment, the semiconductor device 200 is an optical semiconductor configured to convert an optical signal from/to an electrical signal. The semiconductor device 200 has an optical input/output unit 21 configured to input or output an optical signal on one surface (e.g., an upper surface) and an electrode terminal 22 on the other surface (e.g., a lower surface).

In this case, the conductive probe 10 is electrically contacted with the electrode terminal 22 of the semiconductor device 200, and the optical probe 30 is brought close to the optical input/output unit 21 of the semiconductor device 200, during testing. Then, for example, an electrical signal from the tester is provided to the semiconductor device 200 through the conductive probe 10, and then the semiconductor device 200 converts the electrical signal to an optical signal, in response to the electrical signal, and outputs the optical signal from the optical input/output unit 21. The optical signal is returned to the tester through the optical probe 30 and is tested by the tester. Conversely, an optical signal may be supplied to the semiconductor device 200 through the optical probe 30, and an electrical signal output from a semiconductor device 200 may be returned to the tester through the conductive probe 10. In this example, the conductive probe 10 and the optical probe 30 are paired with each other.

It is to be noted that the semiconductor device 200 is not limited to such an optical semiconductor, and may be configured to respond with an electrical signal with respect to an input electrical signal. Alternatively, the semiconductor device 200 may have the electrode terminal 22 on one surface (e.g., the upper surface) and the optical input/output unit 21 on the other surface (e.g., the lower surface).

### [Prober 1]

The prober 1 is configured to test each semiconductor device 200 on the wafer 20.

For example, the prober 1 aligns the optical probe 30 with a position of the optical input/output unit 21 on the one surface (e.g., the upper surface) of the semiconductor device 200 to transmit/receive an optical signal in a non-contact manner, and aligns the conductive probe 10 with the electrode terminal 22 on the other surface (e.g., the lower surface) to be in electrical contact with each other to conduct a test.

The prober 1 includes a plate-shaped air bearing unit 16 on the one surface (e.g., the upper surface) side of the wafer 20, which is capable of air intake/exhaust by being connected to a vacuum pump, so that non-contact probing with the optical probe 30 can be realized.

The air bearing unit 16 is a planar member having an opening 165 in the center portion, and is a wafer non-contact state maintaining unit configured to perform intake/exhaust of pressurized air from/to the wafer 20 to maintain a distance from the wafer 20. Consequently, the wafer 20 can be levitated and the air bearing unit 16 can maintain an attitude of the wafer 20 so as to be in a non-contact state.

Moreover, the air bearing unit 16 also enables access to the semiconductor device 200 on the wafer 20 through the opening 165 while maintaining the wafer 20 in a non-contact state.

The term “access to the semiconductor device 200” used herein is intended to be an approach to work on the semiconductor device 200 under test through the opening 165, for example by probing with probes (any one or both of the optical probe 30 and the conductive probe 10), by blowing hot or cold air, by blowing low-humidity air such as dry air, by applying a magnetic field, or the like.

In this embodiment, probing using the optical probe 30 will now be described as an example of the “access to the semiconductor device 200”.

Although a detailed description of the air bearing unit 16 will be given later, the plate-shaped air bearing unit 16 is capable of relatively separating the air bearing unit 16 and the wafers 20 from each other by exhausting air with respect to the one surface of the wafer 20. Conversely, when the air bearing unit 16 performs air intake with respect to the one surface of the wafer 20, the wafer 20, which has been separated therefrom, can be brought relatively close to the air bearing unit 16 side.

In other words, the air bearing unit 16 can adjust a distance between the air bearing unit 16 and the wafer 20 by controlling an amount of intake and exhaust.

Accordingly, when testing the semiconductor device 200, the distance between the air bearing unit 16 and the wafer 20 can be adjusted by air intake/exhaust performed by the air bearing unit 16, and probing to the optical input/output unit 21 and the electrode terminal 22 of the semiconductor device 200 can be performed respectively with the optical probe 30 and the conductive probe 10, in a state where the wafer 20 is levitated.

Moreover, since the wafer 20 can be levitated, warpage of the wafer 20 can be suppressed. Furthermore, since warping of the wafer 20 can be suppressed, the accuracy of aligning the optical probes 30 and the conductive probes 10 can be improved with respect to the optical input/output unit 21 and the electrode terminal 22 of the semiconductor device 200.

### [Conductive Probe Assembly 11]

The conductive probe assembly 11 includes a plurality of conductive probes 10.

The conductive probe assembly 11 is placed on the conductive probe stage 12, which is movable in an up-and-down direction (Z-axial direction), and is configured to electrically contact the conductive probe 10 with the electrode terminal 22 of the semiconductor device 200 when testing the semiconductor device 200.

The conductive probe assembly 11 is connected to the electrical signal transmitter/receiver unit 18, and provides the electrical signal to the semiconductor device 200 and provides the electrical signal from the semiconductor device 200 to the electrical signal transmitter/receiver unit 18 through the conductive probe 10.

The conductive probe 10 is electrically contacted with the electrode terminal 22 of the semiconductor device 200.

### [Alignment Camera 13]

The alignment camera 13 is a camera configured to capture the other surface (e.g., the lower surface) side of the wafer 20 in order to verify a position, a contact state, etc. of the conductive probe 10 with respect to the electrode terminal 22 of the semiconductor device 200. A video image captured by the alignment camera 13 is provided to the inspection apparatus, and the video image is displayed on a display unit of the inspection apparatus.

### [Optical Probe 30]

The optical probe 30 is, for example, an optical fiber, and transmits/receives the optical signal to/from the optical input/output unit 21 of the semiconductor device 200 in a non-contact manner. The optical probe 30 transmits the optical signal from the optical transmitter/receiver unit 17 to the optical input/output unit 21 of the semiconductor device 200, and receives the optical signal from the optical input/output unit 21 to be provided to the optical transmitter/receiver unit 17.

### [Optical Probe Manipulator 15]

The optical probe manipulator 15 performs an alignment operation for the optical probe 30.

### [Wafer Drive Mechanism Unit 14]

The wafer drive mechanism unit 14 receives a drive force from a drive unit such as a motor (not illustrated) and moves the wafer 20 freely in X, Y, and θ directions. The wafer drive mechanism unit 14 includes a wafer fixing mechanism unit 141 which fixes a peripheral edge of the approximately circular wafer 20, an X stage 142 which moves the fixed wafer 20 in the X direction on a plane, and a Y stage 143 which moves the fixed wafer 20 in the Y direction on a plane.

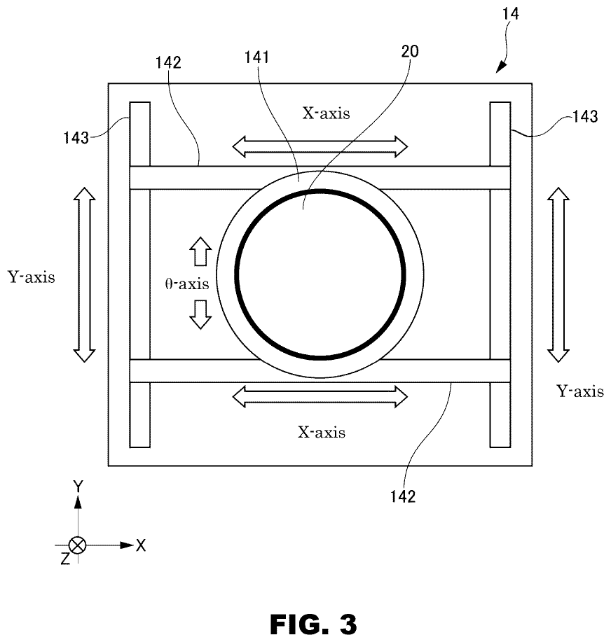

FIG. 3 is a top view diagram illustrating a configuration of the wafer drive mechanism unit 14 according to the embodiment in a plan view.

As illustrated in FIG. 3, the wafer fixing mechanism unit 141 fixes the peripheral edge of the wafer 20 by vacuum suction or the like, and makes it possible movement in the X, Y, and θ directions so that the semiconductor device 200 under test is positioned at a center portion among the plurality of semiconductor devices 200 on the wafer 20.

When moving in the X-axis direction, the wafer 20 fixed by the wafer fixing mechanism unit 141 moves in the X-axis direction by the X stage 142, and when moving the Y-axis direction, the wafer fixing mechanism unit 141 moves in the Y-axis direction by the Y stage 143. Moreover, the wafer fixing mechanism unit 141 which fixes the wafer 20 moves (rotates) in the θ-axis direction, thereby enabling movement in the θ-axis direction.

Consequently, non-contact probing can be performed by the optical probe 30 with respect to the optical input/output unit 21 of the semiconductor device 200 under test, and probing can be performed by electrically contacting the conductive probe 10 with the electrode terminal 22.

### [Air Bearing Unit 16]

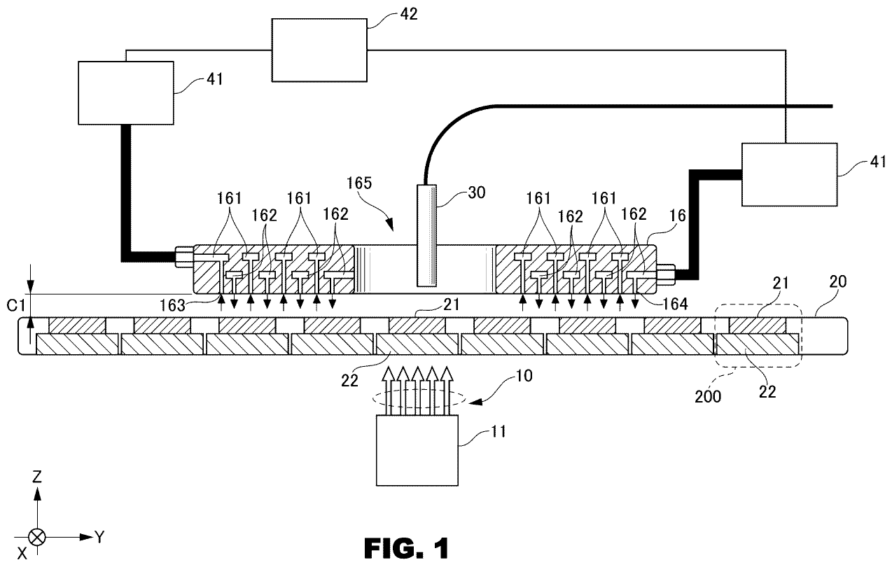

FIG. 1 is an explanatory diagram for explaining a structure of the air bearing unit 16 and the wafer 20 according to the embodiment.

A plurality of semiconductor devices 200 each having the optical input/output unit 21 and the electrode terminal 22 are formed in the wafer 20.

As illustrated in FIG. 1, the plate-shaped air bearing unit 16 has the opening 165 formed in the center portion, and is configured so that the optical probe 30 can be aligned with the optical input/output unit 21 of the semiconductor device 200 under test through the opening 165. Moreover, the conductive probe 10 can be electrically contacted with the electrode terminal 22 of the semiconductor device 200 under test.

The shape of the opening 165 in a plan view is not particularly limited, but it may be, for example, rectangular, circular, elliptical, or the like. Moreover, the size of the opening 165 in a plan view is larger than the size of the semiconductor device 200. For example, when a plurality of semiconductor devices 200 are simultaneously tested, the size of the opening 165 in a plan view can be made larger than the size of the plurality of semiconductor devices 200 to be simultaneously tested.

Moreover, the outer shape of the air bearing unit 16 in a plan view is not particularly limited, but may be, for example, rectangular, circular, or the like.

An intake/exhaust control unit 42 is configured to control an amount of intake and exhaust of the vacuum pump 41, and a vacuum pump 41 is connected to the air bearing unit 16.

Various methods can be widely applied hereto as a control method of the intake/exhaust control unit 42. For example, a distance between the air bearing unit 16 and the wafer 20 (i.e., levitating height) is detected by a sensor (e.g., a light transmitting sensor, a light receiving sensor, etc.), and the intake/exhaust control unit 42 controls an amount of intake and exhaust so that the distance becomes a predetermined value.

A plurality of intake pipes 161 and a plurality of exhaust pipes 162 each connected to with a vacuum pump 41 are arranged inside the air bearing unit 16, and intake holes 163 respectively connected to the intake pipes 161 and exhaust holes 164 respectively connected to the exhaust pipes 162 are provided on the other surface (e.g., the lower surface) of the air bearing unit 16.

That is, the lower surface of the air bearing unit 16 has a porous structure as the intake holes 163 and the exhaust holes 164, and the wafer 20 is levitated by air intake/exhaust performed by the vacuum pump 41.

In a state where the wafer 20 is levitated, the optical probe 30 is required to efficiently transmit and receive light in a non-contact manner with respect to the optical input/output unit 21 of the semiconductor device 200, and the height of the wafer 20 can be adjusted by the intake/exhaust control unit 42 controlling the amount of intake and exhaust.

Moreover, since the conductive probe 10 is contacted with the other surface (e.g., the lower surface) of the wafer 20, a contact load is generated in a direction from the other surface to the one surface (i.e., from below to above). At this time, even if the contact load acts on the wafer 20, the contact load can be withstood by adjusting the amount of intake and exhaust, and the distance C1 between the air bearing unit 16 and the wafer 20 can be maintained. It is to be noted that the distance C1 may be, for example, approximately 20 um to 40 um, but is not limited to this example.

Thus, warpage of the wafer 20 can be suppressed by levitating the wafer 20 by the air intake and exhaust from the air bearing unit 16 while maintaining the distance C1 between the air bearing unit 16 and the wafer 20.

Moreover, the vacuum pump 41 can adjust the amount of intake and exhaust under the control of the intake/exhaust control unit 42, so that the wafer 20 can be steady levitated. Therefore, when making electrical contact using the conductive probe 10, it is possible to make contact with the wafer 20 having reduced warpage with a uniform pressing amount.

Moreover, the opening 165 is provided in the center portion of the air bearing unit 16, and the optical probe 30 can be inserted into the opening 165 and can be aligned with the optical input/output unit 21 of the semiconductor device 200, thereby realizing non-contact probing.

### (A-2) Modified Examples of Air Bearing Unit 16

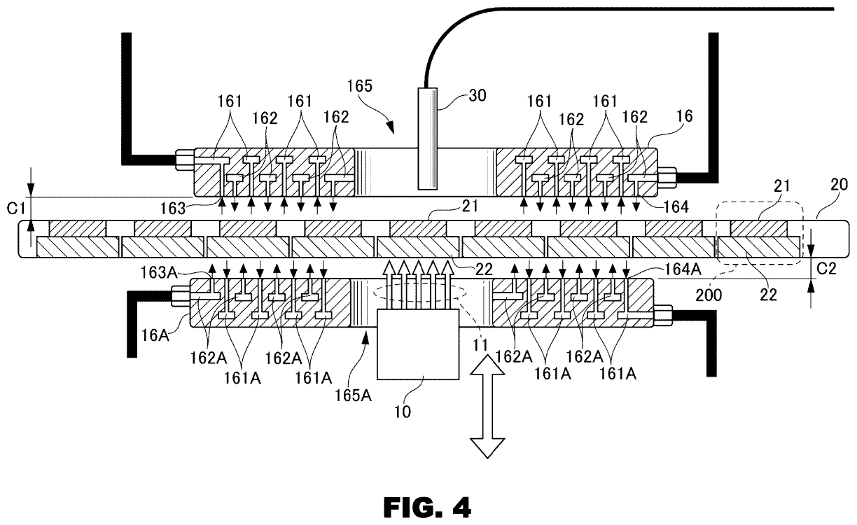

FIG. 4 is an explanatory diagram for explaining a structure of the air bearing unit 16 and the wafer 20 according to a modified embodiment.

As illustrated in FIG. 4, air bearing units 16 and 16A may be respectively provided on both surfaces of the wafer 20.

For example, the air bearing unit 16A on the other surface (e.g., the lower surface) side of the wafer 20 is also similarly capable of intaking/exhausting air with respect to the other surface of the wafer 20. An opening 165A is formed in a center portion of the air bearing unit 16A, and the conductive probe assembly 11 is electrically contacted to the electrode terminal 22 of the semiconductor device 200 through the opening 165A.

It is to be noted that the size of the opening 165A in a plan view is set to a size which allows the conductive probe assembly 11 to be inserted therethrough. Naturally, as long as the conductive probe 10 can be in electrical contact with the electrode terminal 22, the size, shape in a plan view, structure, etc. of the opening 165A are not particularly limited.

The air bearing unit 16 performs air intake and exhaust with respect to the one surface of the wafer 20, and the other air bearing unit 16A performs air intake and exhaust with respect to the other surface of the wafer 20, thereby performing intake and exhaust for both surfaces of the wafer 20 to levitate the wafer 20.

Thus, the wafer 20 can be steadily levitated by providing the air bearing units 16 and 16A respectively on both surfaces of the wafer 20. Moreover, while the wafer 20 is stably levitated, both sides of the wafer 20 can be probed.

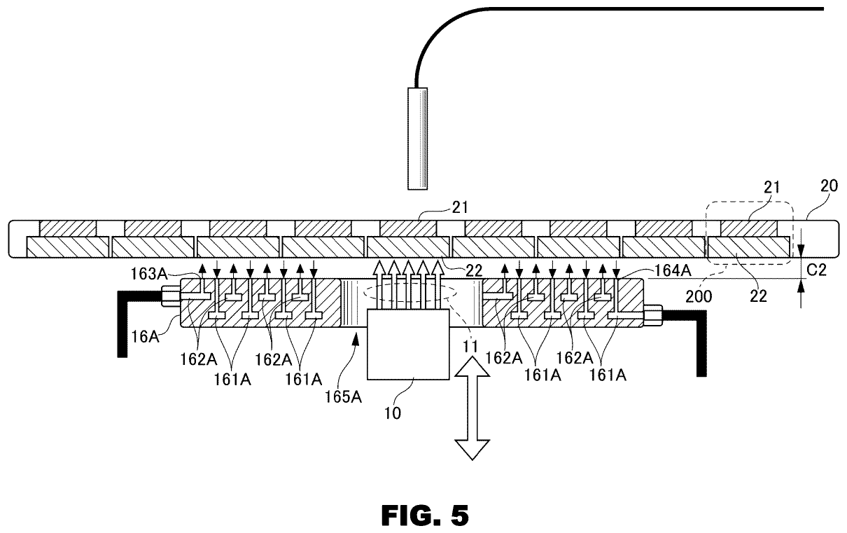

FIG. 5 is an explanatory diagram for explaining a structure of the air bearing unit 16 and the wafer 20 according to a modified embodiment.

In the example illustrated in FIG. 5, the air bearing unit 16 is not provided on the one surface of the wafer 20, but the air bearing unit 16A is provided on the other surface, and therefore the air intake/exhaust can be performed on the other surface of the wafer 20. In this case, the conductive probe assembly 11 can be electrically contacted with the electrode terminal 22 of the semiconductor device 200 through opening 165A in the state where the wafer 20 is levitated and is maintained in a non-contact manner by the air bearing unit 16A. Thus, even when the air bearing unit is provided on any one of both surfaces of the wafer 20, the same effect can be obtained.

### (A-3) Modified Embodiments

Although various modified embodiments have been described in the above-described embodiment, the following modified embodiments can also be applied.

(A-3-1) In the above-described embodiment, the examples have been described in which the air bearing unit 16 is provided on the one surface (e.g., the upper surface) side of the wafer 20, or the air bearing units 16 and 16A are provided on both surfaces thereof. However, it is not limited to this example, and the air bearing unit may be provided on the other surface (e.g., the lower surface) side of the wafer 20.

(A-3-2) For example, the air bearing unit 16 (16A) may include a humidity adjustment unit configured to blow out dry air, such as nitrogen gas or dried air, from the exhaust hole 164.

Consequently, even when humidity at a test point or the like partially increases during testing, the air bearing unit 16 blows dried air, thereby preventing high humidity.

(A-3-3) Moreover, for example, the air bearing unit 16 (16A) may include a temperature adjustment unit configured to blow hot air, cold air, etc. from the exhaust hole 164. In other words, it may be configured to adjust the temperature of the gas to be blown.

Consequently, even when the temperature at the test point becomes locally high or low, it is possible to set the local temperature by blowing hot air, cold air, or the like. Moreover, since the temperature can be locally changed by the air bearing unit 16 (16A), the temperature can be quickly adjusted around the semiconductor device 200.

Further, for example, in the above-described embodiment, the case has been described in which the optical probe 30 and the conductive probe 10 are inserted through the opening 165 (165A) of the air bearing unit 16 (16A) to transmit/receive the light and the electrical signal to/from the semiconductor device 200 on the wafer 20. However, it is not limited to this example, and it is possible to access the semiconductor device 200 by providing the opening 165 (165A), and for example, when testing a magnetic sensor, a magnetic memory, etc., a magnetic field may be applied thereto through the opening 165 (165A).

Moreover, in order to raise or lower the temperature of the wafer 20, a high-temperature plate or a low-temperature plate may be prepared to adjust the temperature of the wafer 20.

### (A-4) Advantageous Effects of Embodiments

As described above, according to the present embodiment, the wafer having the device under test can be stably levitated from the chuck, and one or both surfaces of the wafer can be brought into contact with the terminals of the device under test.

### REFERENCE SIGNS LIST

1: Prober,
10: Conductive probe,
11: Conductive probe assembly,
12: Conductive probe stage,
13: Alignment camera,
14: Wafer drive mechanism unit,
15: Optical probe manipulator,
16, 16A: Air bearing unit,
17: Optical transmitter/receiver unit,
18: Electrical signal transmitter/receiver unit,
19: Control unit,
20: Wafer,
21: Optical input/output unit,
22: Electrode terminal,
30: Optical probe,
41: Vacuum pump,
42: Intake/exhaust control unit,
141: Wafer fixing mechanism unit,
142: X stage,
143: Y stage,
161: Intake pipe,
162: Exhaust pipe,
163: Intake hole,
164: Exhaust hole,
165, 165A: Opening, and
200: Semiconductor device.

1. An inspection apparatus comprising:
a wafer fixing mechanism unit configured to support a wafer, the wafer including a device under test, the device under test having an electrode terminal on one surface and an optical input/output unit on the other surface;
an optical probe provided on the one surface side of the wafer, the optical probe configured to transmit/receive an optical signal to/from the optical input/output units of the device under test;
a conductive probe provided on the other surface side of the wafer, the conductive probe electrically contacted with the electrode terminal of the device under test; and
a wafer non-contact state maintaining unit which is a planar member having an opening in a center portion, the wafer non-contact state maintaining unit configured to maintain a distance from the wafer by intaking/exhausting pressurized air with respect to the wafer and to enable access to the semiconductor device on the wafer through the opening.

2. The inspection apparatus according to claim 1, wherein:
the wafer non-contact state maintaining unit is disposed so that the optical probe provided on the one surface side of the wafer supported by the wafer fixing mechanism unit can be inserted therethrough, and the wafer non-contact state maintaining unit is configured to maintain the wafer in a non-contact state; and
the optical probe is configured to transmit/receive an optical signal to/from the optical input/output units of the device under test through the opening of the wafer non-contact state maintaining unit.

3. The inspection apparatus according to claim 1, wherein:
the wafer non-contact state maintaining unit is disposed so that the conductive probe provided on the other surface side of the wafer supported by the wafer fixing mechanism unit can be inserted therethrough, and the wafer non-contact state maintaining unit is configured to maintain the wafer in a non-contact state; and
the conductive probe is electrically contacted with the electrode terminal of the device under test through the opening of the wafer non-contact state maintaining unit.

4. The inspection apparatus according to claim 1, wherein
the wafer non-contact state maintaining unit includes
a first wafer non-contact state maintaining unit disposed so that the optical probe provided on the one surface side of the wafer supported by the wafer fixing mechanism unit can be inserted therethrough, the wafer non-contact state maintaining unit configured to maintain the wafer in a non-contact state, and
a second wafer non-contact state maintaining unit disposed so that the conductive probe provided on the other surface side of the wafer supported by the wafer fixing mechanism unit can be inserted therethrough, the wafer non-contact state maintaining unit configured to maintain the wafer in a non-contact state, wherein
the optical probe is configured to transmit/receive an optical signal to/from the optical input/output units of the device under test through the opening of the first wafer non-contact state maintaining unit, and
the conductive probe is electrically contacted with the electrode terminal of the device under test through the opening of the second wafer non-contact state maintaining unit.

5. The inspection apparatus according to claim 1, wherein the wafer non-contact state maintaining unit includes a temperature adjustment unit configured to adjusts temperature of the wafer.

6. The inspection apparatus according to claim 1, wherein the wafer non-contact state maintaining unit includes a humidity adjustment unit configured to adjusts humidity of the wafer.
